(19) United States
(12) Patent Application Publication
(10) Pub. No.: US 2026/0007013 A1
(43) Pub. Date: Jan. 1, 2026

(54) DISPLAY APPARATUS

(71) Applicant: Samsung Display Co., LTD., Yongin-si (KR)

(72) Inventors: Sunkwun Son, Yongin-si (KR); Junhyun Park, Yongin-si (KR); Cheolgon Lee, Yongin-si (KR)

(21) Appl. No.: 19/064,531

(22) Filed: Feb. 26, 2025

(30) Foreign Application Priority Data
Jun. 28, 2024 (KR) 10-2024-0085504

(51) Int. Cl. H10K 59/131; H10K 59/121; H10K 59/35

(52) U.S. Cl. CPC H10K 59/131; H10K 59/1213; H10K 59/1216; H10K 59/35

(57) ABSTRACT

A display apparatus includes a first pixel circuit, a second pixel circuit, and a third pixel circuit each including a plurality of transistors, a first capacitor, and a second capacitor, wherein the first pixel circuit, the second pixel circuit, and the third pixel circuit are over a substrate and arranged in a first direction, a first light emitting diode electrically connected to the first pixel circuit, a second light emitting diode electrically connected to the second pixel circuit, and a third light emitting diode electrically connected to the third pixel circuit.

### CROSS-REFERENCE TO RELATED APPLICATION

The present application claims priority to and the benefit of Korean Patent Application No. 10-2024-0085504, filed on Jun. 28, 2024, in the Korean Intellectual Property Office, the entire disclosure of which is incorporated herein by reference.

### BACKGROUND

### 1. Field

Aspects of one or more embodiments relate to a display apparatus.

### 2. Description of the Related Art

Mobility-based apparatuses have been widely used. Recently, in addition to small electronic apparatuses such as mobile phones, tablet personal computers (PCs) have been widely used as mobile electronic apparatuses.

Such mobile electronic apparatuses include a display apparatus to provide visual information such as images or videos to users in order to support various functions. Recently, as other parts for driving a display apparatus have been miniaturized, the proportion of a display apparatus in an electronic apparatus has increased gradually and a structure capable of being bent from a flat state by a certain angle without damaging the display apparatus has also been developed.

The above information disclosed in this Background section is only for enhancement of understanding of the background and therefore the information discussed in this Background section does not necessarily constitute prior art.

### SUMMARY

Aspects of some embodiments include a capacitor with relatively increased capacitance by efficiently arranging lines of a display apparatus.

However, these characteristics are merely examples, and embodiments according to the present disclosure are not limited thereto.

Additional aspects will be set forth in part in the description which follows and, in part, will be apparent from the description, or may be learned by practice of the presented embodiments of the disclosure.

According to some embodiments, a display apparatus includes a first pixel circuit, a second pixel circuit, and a third pixel circuit each including a plurality of transistors, a first capacitor, and a second capacitor, wherein the first pixel circuit, the second pixel circuit, and the third pixel circuit are over a substrate and arranged in a first direction, a first light emitting diode electrically connected to the first pixel circuit, a second light emitting diode electrically connected to the second pixel circuit, a third light emitting diode electrically connected to the third pixel circuit, a horizontal sustain voltage line extending in the first direction, a first-1 initialization horizontal voltage line extending in the first direction and electrically connected to any one of the plurality of transistors of the first pixel circuit, a first-2 initialization horizontal voltage line extending in the first direction and electrically connected to any one of the plurality of transistors of each of the second pixel circuit and the third pixel circuit, a vertical sustain voltage line extending in a second direction intersecting the first direction and electrically connected to the horizontal sustain voltage line, a first-1 initialization vertical voltage line extending in the second direction and electrically connected to the first-1 initialization horizontal voltage line, and a first-2 initialization vertical voltage line extending in the second direction and electrically connected to the first-2 initialization horizontal voltage line.

According to some embodiments, the display apparatus may further include a first connection electrode electrically connecting the first-1 initialization horizontal voltage line and the first-1 initialization vertical voltage line to each other, wherein the first-1 initialization horizontal voltage line, the first-1 initialization vertical voltage line, and the first connection electrode may be arranged on different layers.

According to some embodiments, the first connection electrode may include a first-1 connection electrode portion extending in the first direction and electrically connected to each of any one of the plurality of transistors of the first pixel circuit and the first-1 initialization horizontal voltage line, and a first-2 connection electrode portion extending in the second direction from an end portion of the first-1 connection electrode portion and electrically connected to the first-1 initialization vertical voltage line.

According to some embodiments, the first-1 initialization vertical voltage line may be arranged at a boundary between the first pixel circuit and the second pixel circuit, and at least a portion of the first-2 connection electrode portion may overlap the first-1 initialization vertical voltage line.

According to some embodiments, the first connection electrode may have an island shape and may be spaced apart from another connection electrode arranged on a same layer as the first connection electrode.

According to some embodiments, the display apparatus may further include a second connection electrode electrically connecting the first-2 initialization horizontal voltage line and the first-2 initialization vertical voltage line to each other, wherein the first-2 initialization horizontal voltage line, the first-2 initialization vertical voltage line, and the second connection electrode may be arranged on different layers.

According to some embodiments, the second connection electrode may include a second-1 connection electrode portion extending in the first direction and electrically connected to each of any one of the plurality of transistors of the third pixel circuit and the first-2 initialization horizontal voltage lines, and a second-2 connection electrode portion extending in the second direction from an end portion of the second-1 connection electrode portion and electrically connected to the first-2 initialization vertical voltage line.

According to some embodiments, the first-2 initialization vertical voltage line may be arranged at a boundary between the second pixel circuit and the third pixel circuit, and at least a portion of the second-2 connection electrode portion may overlap the first-2 initialization vertical voltage line.

According to some embodiments, the second connection electrode may have an island shape and may be spaced apart from another connection electrode arranged on a same layer as the second connection electrode.

According to some embodiments, the display apparatus may further include a third connection electrode electrically connecting the horizontal sustain voltage line and the vertical sustain voltage line to each other, wherein the horizontal sustain voltage line, the vertical sustain voltage line, and the third connection electrode may be arranged on different layers.

According to some embodiments, at least a portion of the third connection electrode may overlap the horizontal sustain voltage line.

According to some embodiments, at least a portion of the third connection electrode may overlap the vertical sustain voltage line.

According to some embodiments, the third connection electrode may have an island shape and may be spaced apart from another connection electrode arranged on a same layer as the third connection electrode.

According to some embodiments, the horizontal sustain voltage line, the first-1 initialization horizontal voltage line, and the first-2 initialization horizontal voltage line may be arranged on a same layer.

According to some embodiments, the vertical sustain voltage line, the first-1 initialization vertical voltage line, and the first-2 initialization vertical voltage line may be arranged on a same layer.

According to some embodiments, the first-1 initialization horizontal voltage line, the first-2 initialization horizontal voltage line, and the horizontal sustain voltage line may be sequentially arranged in the second direction.

According to some embodiments, the first-1 initialization vertical voltage line, the first-2 initialization vertical voltage line, and the vertical sustain voltage line may be sequentially arranged in the first direction.

According to some embodiments, the first light emitting diode, the second light emitting diode, and the third light emitting diode may emit light of different colors.

According to some embodiments, the first pixel circuit may include a first-1 pixel circuit and a first-2 pixel circuit arranged in the first direction, and the first light emitting diode may include a first-1 light emitting diode and a first-2 light emitting diode arranged in the first direction.

According to some embodiments, the first-1 light emitting diode and the first-2 light emitting diode may emit light of a same color.

Other aspects, features, and characteristics other than those described above will become apparent from the accompanying drawings, the appended claims, and the detailed description of the disclosure.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a plan view schematically illustrating a display apparatus according to some embodiments;

FIG. 2 is a block diagram schematically illustrating the display apparatus according to some embodiments;

FIG. 3 is an equivalent circuit diagram schematically illustrating a light emitting diode that is a light emitting element corresponding to a pixel of a display apparatus and a pixel circuit electrically connected to the light emitting diode, according to some embodiments;

FIG. 4 is a cross-sectional view schematically illustrating a portion of the display apparatus according to some embodiments;

FIG. 5 is a plan view schematically illustrating a portion of lines arranged in a display area of the display apparatus, according to some embodiments; and

FIGS. 6 to 12 are plan views illustrating a process of forming a pixel circuit included in the display apparatus, according to some embodiments.

### DETAILED DESCRIPTION

Reference will now be made in more detail to aspects of some embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The disclosure may include various embodiments and modifications, and particular embodiments thereof are illustrated in the drawings and will be described herein in more detail. The characteristics and features of embodiments according to the present disclosure and the accomplishing methods thereof will become apparent from the embodiments described below in more detail with reference to the accompanying drawings. However, embodiments according to the present disclosure are not limited to the embodiments described below, and may be embodied in various modes.

Hereinafter, aspects of some embodiments will be described in more detail with reference to the accompanying drawings, and in the following description, like reference numerals will denote like elements and redundant descriptions thereof will be omitted.

It will be understood that although terms such as “first” and “second” may be used herein to describe various elements, these elements should not be limited by these terms and these terms are only used to distinguish one element from another element.

As used herein, the singular forms “a,” “an,” and “the” are intended to include the plural forms as well, unless the context clearly indicates otherwise.

Also, it will be understood that the terms “comprise,” “include,” and “have” used herein specify the presence of stated features or elements, but do not preclude the presence or addition of one or more other features or elements.

It will be understood that when a layer, region, area, component, or element is referred to as being “on” another layer, region, area, component, or element, it may be “directly on” the other layer, region, area, component, or element or may be “indirectly on” the other layer, region, area, component, or element with one or more intervening layers, regions, areas, components, or elements therebetween.

Sizes of elements in the drawings may be exaggerated for convenience of description. In other words, because the sizes and shapes of components in the drawings are arbitrarily illustrated for convenience of description, embodiments according to the present disclosure are not limited thereto.

As used herein, the x-axis, the y-axis, and the z-axis are not limited to three axes of the rectangular coordinate system and may be interpreted in a broader sense. For example, the x-axis, y-axis, and z-axis may be perpendicular to each other or may refer to different directions that are not perpendicular to each other.

When a certain embodiment may be implemented differently, a particular process order may be performed differently from the described order. For example, two processes described in succession may be performed substantially at the same time or may be performed in an order opposite to the described order.

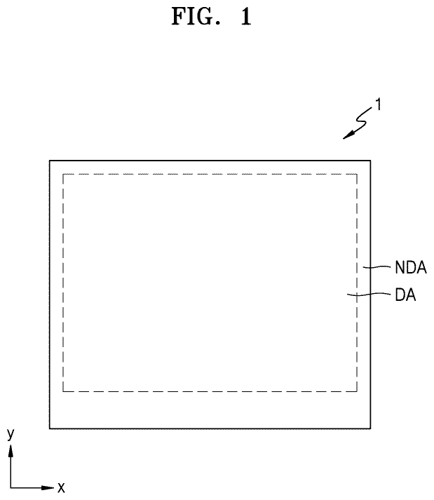

FIG. 1 is a plan view schematically illustrating a display apparatus 1 according to some embodiments.

Referring to FIG. 1, the display apparatus 1 may include a display area DA configured to display images and a non-display area NDA outside (e.g., in a periphery or outside a footprint of) the display area DA. The display area DA may be entirely surrounded by the non-display area NDA.

In a plan view (e.g., a view in a direction perpendicular or normal with respect to a display surface of the display apparatus 1), the display area DA may have a rectangular shape. According to some embodiments, the display area DA may have a polygonal shape such as a triangular, pentagonal, or hexagonal shape, a circular shape, an elliptical shape, an atypical shape, or the like. According to some embodiments, corners of an edge of the display area DA may be rounded.

The display apparatus 1 of FIG. 1 may be an apparatus capable of displaying moving images (e.g., video images) or still images (e.g., static images) and may be used in portable electronic apparatuses such as mobile phones, laptop computers, tablet personal computers (PCs), smart phones, mobile communication terminals, electronic notebooks, electronic books, portable multimedia players (PMPs), navigation apparatuses, or ultra mobile PCs (UMPCs). Alternatively, the display apparatus 1 may be used in televisions, monitors, billboards, and electronic apparatuses for Internet of Things (IoT) or may be used in wearable electronic apparatuses such as smart watches, watch phones, glasses-type displays, and head-mounted displays (HMDs). Also, the display apparatus 1 according to some embodiments may be applied to a center information display (CID) arranged at a vehicle's instrument panel or a vehicle's center fascia or dashboard, a room mirror display replacing a vehicle's side mirror, or a display electronic apparatus arranged at a rear side of a vehicle's front seat as entertainment for a vehicle's rear seat.

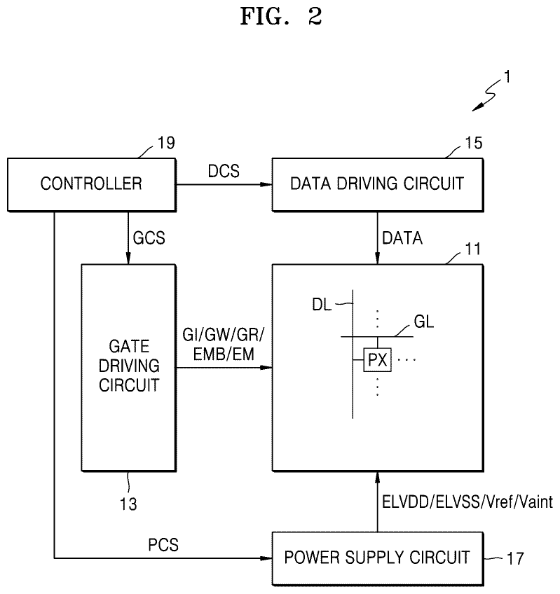

FIG. 2 is a block diagram schematically illustrating the display apparatus 1 according to some embodiments.

Referring to FIGS. 1 and 2, the display apparatus 1 according to some embodiments may include a pixel unit 11, a gate driving circuit 13, a data driving circuit 15, a power supply circuit 17, and a controller 19.

The pixel unit 11 may include a plurality of pixels PX arranged in the display area DA (see FIG. 1). The plurality of pixels PX may be arranged in various forms such as a stripe arrangement, a pentile™ arrangement (diamond arrangement), and a mosaic arrangement to implement an image. Each of the plurality of pixels PX may include a display element (e.g., a light emitting diode), and the display element may be electrically connected to a pixel circuit. The plurality of pixels PX may represent an image by using light emitted from a display element corresponding to each of the plurality of pixels PX. The pixel circuit may be electrically connected to a gate line GL and a data line DL and may include a plurality of transistors and at least one capacitor.

Various conductive lines for transmitting electrical signals to be applied to the display area DA (see FIG. 1), peripheral circuits electrically connected to pixel circuits, and/or pads to which a printed circuit board or a driver IC chip is attached may be located in the non-display area NDA (see FIG. 1). For example, the gate driving circuit 13, the data driving circuit 15, the power supply circuit 17, and the controller 19 may be provided in the non-display area NDA (see FIG. 1).

The gate driving circuit 13 may be electrically connected to a plurality of gate lines GL, may generate a gate signal in response to a control signal GCS from the controller 19, and may sequentially supply the gate signal to the gate lines GL. The gate signal may be a gate control signal for controlling turn-on and turn-off of the transistor electrically connected to the gate line GL. The gate signal may be a square wave signal including an on voltage at which the transistor may be turned on and an off voltage at which the transistor may be turned off. According to some embodiments, the on voltage may be a high-level voltage (first-level voltage) or a low-level voltage (second-level voltage).

FIG. 2 illustrates that a pixel circuit corresponding to a pixel PX is connected to a gate line GL. However, this is merely an example and a pixel circuit corresponding to a pixel PX may be connected to two or more gate lines and the gate driving circuit 13 may supply, to the corresponding gate lines, two or more gate signals with different timings when an on voltage is applied. For example, the pixel circuit may be connected to first to fifth gate lines, and the gate driving circuit 13 may apply a first gate signal GW, a second gate signal GR, a third gate signal EM, a fourth gate signal GI, and a fifth gate signal EMB to the first gate line, the second gate line, the third gate line, the fourth gate line, and the fifth gate line respectively. The third gate signal EM may be an emission control signal for controlling turn-on and turn-off of the transistor whose gate is connected to the third gate line.

The data driving circuit 15 may be connected to a plurality of data lines DL and may supply a data signal to the data lines DL in response to a control signal DCS from the controller 19. The data signal supplied to the data line DL may be supplied to the pixel circuit. The data driving circuit 15 may convert input image data with gradation input from the controller 19, into a data signal in the form of a voltage or current.

The power supply circuit 17 may generate voltages necessary for driving the pixel PX, in response to a control signal PCS from the controller 19. The power supply circuit 17 may generate a driving voltage ELVDD and a common voltage ELVSS and supply the same to the pixels PX. The driving voltage ELVDD may be a high-level voltage provided to a first electrode (pixel electrode or anode) of the display element included in the pixel PX. The common voltage ELVSS may be a low-level voltage provided to a second electrode (opposite electrode or cathode) of the display element included in the pixel PX. The power supply circuit 17 may generate a reference voltage Vref and a first initialization voltage Vaint and supply the same to the pixels PX.

The voltage level of the driving voltage ELVDD may be higher than the voltage level of the common voltage ELVSS. The voltage level of the reference voltage Vref may be lower than the voltage level of the driving voltage ELVDD. The voltage level of the first initialization voltage Vaint may be equal to or higher than the voltage level of the common voltage ELVSS.

The controller 19 may generate control signals GCS, DCS, and PCS based on signals input from outside and supply the same to the gate driving circuit 13, the data driving circuit 15, and the power supply circuit 17. The control signal GCS output to the gate driving circuit 13 may include a plurality of clock signals and a gate start signal. The control signal DCS output to the data driving circuit 15 may include a source start signal and clock signals.

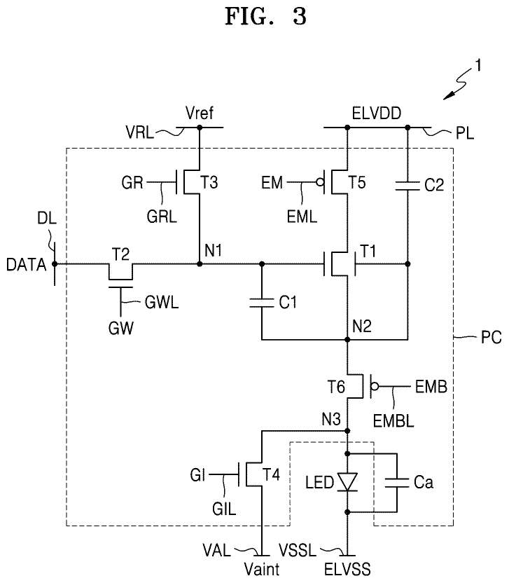

FIG. 3 is an equivalent circuit diagram schematically illustrating a light emitting diode LED that is a light emitting element corresponding to a pixel of the display apparatus 1 and a pixel circuit PC electrically connected to the light emitting diode LED, according to some embodiments. Although FIG. 3 illustrates various components in a pixel circuit PC according to some embodiments of the present disclosure, embodiments according to the present disclosure are not limited thereto, and according to some embodiments, the pixel circuit PC may include additional components or fewer components without departing from the spirit and scope of embodiments according to the present disclosure.

The pixel circuit PC may be electrically connected to a first gate line GWL configured to transmit a first gate signal GW, a second gate line GRL configured to transmit a second gate signal GR, a third gate line EML configured to transmit a third gate signal EM, a fourth gate line GIL configured to transmit a fourth gate signal GI, a fifth gate line EMBL configured to transmit a fifth gate signal EMB, and a data line DL configured to transmit a data signal DATA. Because the light emission of a light emitting diode LED is controlled by the third gate signal EM and the fifth gate signal EMB, the third gate signal EM and the fifth gate signal EMB may be referred to as an emission control signal and the third gate line EML and the fifth gate line EMBL may be referred to as an emission control line. The pixel circuit PC may be electrically connected to a driving voltage line PL configured to transmit a driving voltage ELVDD, a reference voltage line VRL configured to transmit a reference voltage Vref, and a first initialization voltage line VAL configured to transmit a first initialization voltage Vaint.

According to some embodiments, some of a plurality of transistors included in the pixel circuit PC may be N-type transistors and the others may be P-type transistors. The first to fourth transistors T1, T2, T3, and T4 may be N-type transistors, and the fifth and sixth transistors T5 and T6 may be P-type transistors. The semiconductor layers of the first to fourth transistors T1, T2, T3, and T4 may include a different material than the semiconductor layers of the fifth and sixth transistors T5 and T6. According to some embodiments, the first to fourth transistors T1, T2, T3, and T4 may include a semiconductor layer including an oxide, and the fifth and sixth transistors T5 and T6 may include amorphous silicon, polysilicon, or an organic semiconductor.

The pixel circuit PC may include first to sixth transistors T1, T2, T3, T4, T5, and T6, first and second capacitors C1 and C2, and an auxiliary capacitor Ca. The first transistor T1 may be a driving transistor outputting a driving current corresponding to the data signal DATA, and the second to sixth transistors T2, T3, T4, T5, and T6 may be switching transistors configured to transmit signals. A first terminal (or a first electrode) and a second terminal (or a second electrode) of each of the first to sixth transistors T1, T2, T3, T4, T5, and T6 may be a source (or a source electrode) or a drain (or a drain electrode) depending on the voltages of the first terminal and the second terminal. For example, depending on the voltages of the first terminal and the second terminal, the first terminal may be a drain and the second terminal may be a source, or the first terminal may be a source and the second terminal may be a drain. Hereinafter, a node to which a first-1 gate electrode of the first transistor T1 is connected may be defined as a first node N1, and a node to which a second terminal of the first transistor T1 is connected may be defined as a second node N2.

The first transistor T1 may be connected to the driving voltage line PL and the light emitting diode LED. The first transistor T1 may be connected between the fifth transistor T5 and the sixth transistor T6. The first transistor T1 may include a first gate (or a first gate electrode), a first terminal, and a second terminal connected to the second node N2. The first transistor T1 may include a first-1 gate connected to the first node N1. The first transistor T1 may further include a first-2 gate connected to the second terminal thereof. The first-1 gate and the first-2 gate may be arranged on different layers to face each other. For example, the first-1 gate and the first-2 gate of the first transistor T1 may face each other with a semiconductor layer therebetween. Herein, the first gate (or the first gate electrode) of the first transistor T1 may refer to the first-1 gate (or the first-1 gate electrode) involved in turning on and off the first transistor T1.

The gate (or the first-1 gate) of the first transistor T1 may be connected to the second terminal of the second transistor T2, the first terminal of the third transistor T3, and the first capacitor C1. The first-2 gate of the first transistor T1 may be connected to the first terminal of the sixth transistor T6, the first capacitor C1, and the second capacitor C2. The first terminal of the first transistor T1 may be connected to the driving voltage line PL via the fifth transistor T5, and the second terminal thereof may be connected to the pixel electrode of the light emitting diode LED via the sixth transistor T6. The first terminal of the first transistor T1 may be connected to the second terminal of the fifth transistor T5. The second terminal of the first transistor T1 may be connected to the first terminal of the sixth transistor T6, the first capacitor C1, and the second capacitor C2. The first transistor T1 may receive a data signal DATA according to a switching operation of the second transistor T2 to control the amount of a driving current flowing through the light emitting diode LED.

The second transistor T2 may be connected to the data line DL and the gate of the first transistor T1. The second transistor T2 may include a gate connected to the first gate line GWL, a first terminal connected to the data line DL, and a second terminal connected to the first node N1. The second terminal of the second transistor T2 may be connected to the gate of the first transistor T1, the first terminal of the third transistor T3, and the first capacitor C1. The second transistor T2 may be turned on by the first gate signal GW received through the first gate line GWL, to electrically connect the data line DL with the first node N1 and transmit the data signal DATA received through the data line DL, to the first node N1.

The third transistor T3 may be connected to the gate of the first transistor T1 and the reference voltage line VRL. The third transistor T3 may include a gate connected to the second gate line GRL, a first terminal connected to the first node N1, and a second terminal connected to the reference voltage line VRL. The first terminal of the third transistor T3 may be connected to the gate of the first transistor T1, the second terminal of the second transistor T2, and the first capacitor C1. The third transistor T3 may be turned on by the second gate signal GR received through the second gate line GRL, to transmit the reference voltage Vref received through the reference voltage line VRL, to the first node N1.

The fourth transistor T4 may be connected to the sixth transistor T6 and the first initialization voltage line VAL. The fourth transistor T4 may be connected to the light emitting diode LED and the first initialization voltage line VAL. The fourth transistor T4 may include a gate connected to the fourth gate line GIL, a first terminal connected to a third node N3, and a second terminal connected to the first initialization voltage line VAL. The first terminal of the fourth transistor T4 may be connected to the second terminal of the sixth transistor T6 and the pixel electrode of the light emitting diode LED. The fourth transistor T4 may be turned on by the fourth gate signal GI received through the fourth gate line GIL, to transmit the first initialization voltage Vaint received through the first initialization voltage line VAL, to the third node N3 and initialize the pixel electrode (e.g., the anode) of the light emitting diode LED.

The fifth transistor T5 may be connected to the driving voltage line PL and the first transistor T1. The fifth transistor T5 may include a gate connected to the third gate line EML, a first terminal connected to the driving voltage line PL, and a second terminal connected to the first terminal of the first transistor T1. The fifth transistor T5 may be turned on or off according to the third gate signal EM received through the third gate line EML.

The sixth transistor T6 may be connected to the first transistor T1 and the light emitting diode LED. The sixth transistor T6 may be connected between the second node N2 and the third node N3. The sixth transistor T6 may include a gate connected to the fifth gate line EMBL, a first terminal connected to the second node N2, and a second terminal connected to the third node N3. The first terminal of the sixth transistor T6 may be connected to the second terminal of the first transistor T1, the first capacitor C1, and the second capacitor C2. The second terminal of the sixth transistor T6 may be connected to the first terminal of the fourth transistor T4 and the pixel electrode of the light emitting diode LED. The sixth transistor T6 may be turned on or off according to the fifth gate signal EMB received through the fifth gate line EMBL.

The first capacitor C1 may be connected between the gate of the first transistor T1 and the second terminal of the first transistor T1. The first electrode of the first capacitor C1 may be connected to the first node N1, and the second electrode thereof may be connected to the second node N2. The first electrode of the first capacitor C1 may be connected to the gate of the first transistor T1, the second terminal of the second transistor T2, and the first terminal of the third transistor T3. The second electrode of the first capacitor C1 may be connected to the second terminal and the first-2 gate of the first transistor T1, the second electrode of the second capacitor C2, and the first terminal of the sixth transistor T6. The first capacitor C1 may be a storage capacitor and may store a threshold voltage of the first transistor T1 and a voltage corresponding to the data signal DATA.

The first transistor T1 may be turned on when the third transistor T3 and the fifth transistor T5 are turned on. When the voltage of the second terminal of the first transistor T1 drops to the difference (Vref−Vth1) between the reference voltage Vref and the threshold voltage (Vth1) of the first transistor T1, the first transistor T1 may be turned off and a voltage corresponding to the threshold voltage (Vth1) of the first transistor T1 may be stored in the first capacitor C1 and thus the threshold voltage (Vth1) of the first transistor T1 may be compensated.

The second capacitor C2 may be connected between the driving voltage line PL and the second node N2. The first electrode of the second capacitor C2 may be connected to the driving voltage line PL. The second electrode of the second capacitor C2 may be connected to the second terminal and the first-2 gate of the first transistor T1, the second electrode of the first capacitor C1, and the first terminal of the sixth transistor T6.

The capacitance of each of the first capacitor C1 and the second capacitor C2 may vary depending on the color of light emitted from the light emitting diode LED.

The auxiliary capacitor Ca may be electrically connected to the sixth transistor T6, a sustain voltage line VSSL, and the pixel electrode of the light emitting diode LED. The auxiliary capacitor Ca may store and maintain a voltage corresponding to the voltage difference between the pixel electrode of the light emitting diode LED and the sustain voltage line VSSL, thereby preventing or reducing the problem of the black luminance increasing when the sixth transistor T6 is turned off.

The light emitting diode LED may be connected to the first transistor T1 through the sixth transistor T6. The light emitting diode LED may include a pixel electrode (anode) connected to the third node N3 and an opposite electrode (cathode) facing the pixel electrode, and the opposite electrode may receive a common voltage ELVSS. According to some embodiments, the opposite electrode (cathode) may extend into the display area and thus may be electrically connected to the sustain voltage line VSSL configured to provide the common voltage ELVSS. The driving current output by the first transistor T1 may flow through the light emitting diode LED due to the turned-on fifth transistor T5 and the turned-on sixth transistor T6, and the light emitting diode LED may emit light with a brightness corresponding to the driving current.

Although FIG. 3 illustrates that the pixel circuit PC includes sixth transistors, embodiments according to the present disclosure are not limited thereto. According to some embodiments, the number of transistors in the pixel circuit PC may be 5 or less or 7 or more.

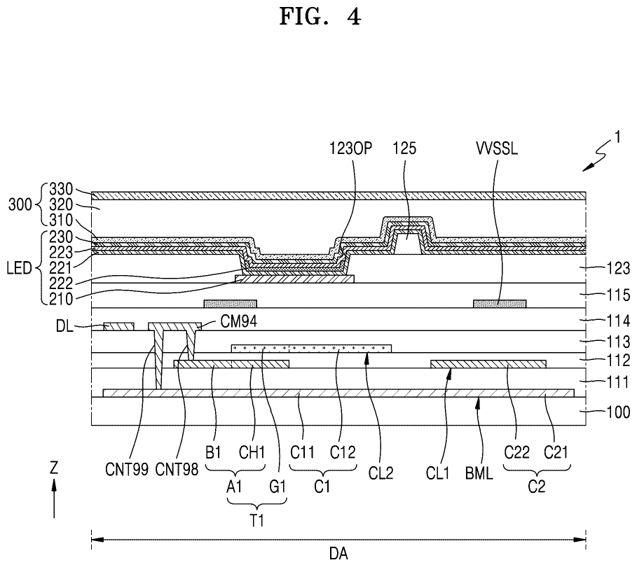

FIG. 4 is a cross-sectional view schematically illustrating a portion of the display apparatus 1 according to some embodiments.

Referring to FIG. 4, the display apparatus 1 may include a light emitting diode LED arranged in a display area DA. The light emitting diode LED may be located over a substrate 100, and a pixel circuit PC may be arranged between the substrate 100 and the light emitting diode LED. According to some embodiments, FIG. 4 illustrates a first transistor T1, a first capacitor C1, and a second capacitor C2 as some components of the pixel circuit PC.

The substrate 100 may include a glass material or a polymer resin. According to some embodiments, the substrate 100 may have an alternating stack structure of a base layer including a polymer resin and a barrier layer including an inorganic insulating material such as silicon oxide or silicon nitride. The polymer resin may include a polymer resin such as polyether sulfone, polyarylate, polyether imide, polyethylene naphthalate, polyethylene terephthalate, polyphenylene sulfide, polyimide, polycarbonate, cellulose triacetate, or cellulose acetate propionate.

A bottom metal layer BML may be located over the substrate 100. The bottom metal layer BML may function as a first electrode C11 of the first capacitor C1 and a first electrode C21 of the second capacitor C2. That is, the bottom metal layer BML may include the first electrode C11 of the first capacitor C1 and the first electrode C21 of the second capacitor C2. The first electrode C11 of the first capacitor C1 and the first electrode C21 of the second capacitor C2 may be located over the substrate 100.

According to some embodiments, a first-11 gate line GWL1-1, a first-21 gate line GWL2-1, a reference voltage line VRL, a driving voltage line PL, a horizontal sustain voltage line HVSSL, a first-11 initialization horizontal voltage line HVAL(R)1, and a first-2 initialization horizontal voltage line HVAL(GB) may be additionally located over the substrate 100.

The bottom metal layer BML may include one or more materials among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). According to some embodiments, the bottom metal layer BML may be a single layer of molybdenum, may have a bilayer structure in which a molybdenum layer and a titanium layer are stacked, or may have a trilayer structure in which a titanium layer, an aluminum layer, and a titanium layer are stacked.

The first-11 gate line GWL1-1, the first-21 gate line GWL2-1, the reference voltage line VRL, the driving voltage line PL, the horizontal sustain voltage line HVSSL, the first-11 initialization horizontal voltage line HVAL(R)1, and the first-2 initialization horizontal voltage line HVAL(GB) may include the same material as the bottom metal layer BML.

A first insulating layer 111 may be located over the substrate 100 to cover the bottom metal layer BML. The first insulating layer 111 may be located over the first electrode C11 of the first capacitor C1 and the first electrode C21 of the second capacitor C2. The first insulating layer 111 may include an inorganic insulating material such as silicon oxide, silicon nitride, or silicon oxynitride and may include a single-layer or multiple-layer structure including the inorganic insulating material. A semiconductor layer and a first conductive layer CL1 may be located over the first insulating layer 111.

The semiconductor layer may be located over the first insulating layer 111. In this regard, FIG. 4 illustrates that a first semiconductor layer A1 of the first transistor T1 is located over the first insulating layer 111. The first semiconductor layer A1 may include a channel area CH1 and doped areas arranged on both sides of the channel area CH1, and in this regard, FIG. 4 illustrates a first area B1 that is one of the doped areas arranged on one side of the channel area CH1.

The first semiconductor layer A1 may include an oxide of at least one of indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), or zinc (Zn). For example, the first semiconductor layer A1 may include an InSnZnO (ITZO) semiconductor layer or an InGaZnO (IGZO) semiconductor layer. A conductive (or conduction) process based on, for example, plasma treatment may be performed on at least a portion of the first semiconductor layer A1.

The first conductive layer CL1 may be located over the first insulating layer 111. The first conductive layer CL1 may function as a second electrode C22 of the second capacitor C2. That is, the first conductive layer CL1 may include the second electrode C22 of the second capacitor C2. The second electrode C22 of the second capacitor C2 may be located over the first insulating layer 111.

The first conductive layer CL1 may include one or more materials among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). According to some embodiments, the first conductive layer CL1 may be a single layer of molybdenum, may have a bilayer structure in which a molybdenum layer and a titanium layer are stacked, or may have a trilayer structure in which a titanium layer, an aluminum layer, and a titanium layer are stacked.

A second insulating layer 112 may be located over the first insulating layer 111 to cover the first semiconductor layer A1 and the first conductive layer CL1. The second insulating layer 112 may be located over the first semiconductor layer A1 and the second electrode C22 of the second capacitor C2. The second insulating layer 112 may include an inorganic insulating material such as silicon oxide, silicon nitride, or silicon oxynitride and may include a single-layer or multiple-layer structure including the inorganic insulating material.

A second conductive layer CL2 may be located over the second insulating layer 112. The second conductive layer CL2 may function as a first gate electrode G1 and a second electrode C12 of the first capacitor C1. That is, the second conductive layer CL2 may include the first gate electrode G1 and the second electrode C12 of the first capacitor C1. The first gate electrode G1 and the second electrode C12 of the first capacitor C1 may be located over the second insulating layer 112. The first gate electrode G1 may overlap the channel area CH1 of the first semiconductor layer A1 with the second insulating layer 112 therebetween.

According to some embodiments, a first-12 gate line GWL1-2, a first-22 gate line GWL2-2, a second gate line GRL, a third gate line EML, a fourth gate line GIL, a fifth gate line EMBL, and a first-12 initialization horizontal voltage line HVAL(R)2 may be additionally located over the second insulating layer 112.

The second conductive layer CL2 may include at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), or copper (Cu). According to some embodiments, the second conductive layer CL2 may be a single layer of molybdenum, may have a bilayer structure in which a molybdenum layer and a titanium layer are stacked, or may have a trilayer structure in which a titanium layer, an aluminum layer, and a titanium layer are stacked.

The first-12 gate line GWL1-2, the first-22 gate line GWL2-2, the second gate line GRL, the third gate line EML, the fourth gate line GIL, the fifth gate line EMBL, and the first-12 initialization horizontal voltage line HVAL(R)2 may include the same material as the second conductive layer CL2.

A third insulating layer 113 may be located over the second insulating layer 112 to cover the second conductive layer CL2. The third insulating layer 113 may be located over the first gate electrode G1 and the second electrode C12 of the first capacitor C1. The third insulating layer 113 may include an inorganic insulating material such as silicon oxide, silicon nitride, or silicon oxynitride and may include a single-layer or multiple-layer structure including the inorganic insulating material.

A data line DL and a 94th connection electrode CM94 may be located over the third insulating layer 113. The 94th connection electrode CM94 may be connected to the first semiconductor layer A1 of the first transistor T1 through a 98th contact hole CNT98. The 94th connection electrode CM94 may be connected to the bottom metal layer BML through a 99th contact hole CNT99. That is, the 94th connection electrode CM94 may be connected to each of the first transistor T1 and the bottom metal layer BML.

According to some embodiments, a plurality of connection electrodes may be located over the third insulating layer 113 in addition to the 94th connection electrode CM94.

The data line DL and the 94th connection electrode CM94 may include one or more materials among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). According to some embodiments, the data line EL and the 94th connection electrode CM94 may be a single layer of molybdenum, may have a bilayer structure in which a molybdenum layer and a titanium layer are stacked, or may have a trilayer structure in which a titanium layer, an aluminum layer, and a titanium layer are stacked.

The plurality of connection electrodes may include the same material as the data line DL and the 94th connection electrode CM94.

A fourth insulating layer 114 may be located over the third insulating layer 113 to cover the data line DL and the 94th connection electrode CM94. The fourth insulating layer 114 may be located over the data line DL and the 94th connection electrode CM94. The fourth insulating layer 114 may include an organic insulating material such as acryl, benzocyclobutene (BCB), polyimide, or hexamethyldisiloxane (HMDSO).

A vertical sustain voltage line VVSSL may be located over the fourth insulation layer 114.

According to some embodiments, a first-1 initialization vertical voltage line VVAL(R) and a first-2 initialization vertical voltage line VVAL(GB) may be additionally located over the fourth insulation layer 114.

The vertical sustain voltage line VVSSL may include one or more materials among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). According to some embodiments, the vertical sustain voltage line VVSSL may be a single layer of molybdenum, may have a bilayer structure in which a molybdenum layer and a titanium layer are stacked, or may have a trilayer structure in which a titanium layer, an aluminum layer, and a titanium layer are stacked.

The first-1 initialization vertical voltage line VVAL(R) and the first-2 initialization vertical voltage line VVAL(GB) may include the same material as the vertical sustain voltage line VVSSL.

A fifth insulating layer 115 may be located over the fourth insulating layer 114 to cover the vertical sustain voltage line VVSSL. The fifth insulating layer 115 may be located over the vertical sustain voltage line VVSSL. The fifth insulating layer 115 may include an organic insulating material such as acryl, benzocyclobutene (BCB), polyimide, or hexamethyldisiloxane (HMDSO).

The light emitting diode LED may include a pixel electrode 210, an emission layer 222, and an opposite electrode 230.

The pixel electrode 210 may be located over the fifth insulating layer 115. The pixel electrode 210 may include a reflective layer (e.g., having light reflecting properties) including at least one of silver (Ag), magnesium (Mg), aluminum (Al), platinum (Pt), palladium (Pd), gold (Au), nickel (Ni), neodymium (Nd), iridium (Ir), chromium (Cr), or any compound thereof. According to some embodiments, the pixel electrode 210 may further include a conductive oxide layer over and/or under the reflective layer. The conductive oxide layer may include indium tin oxide (ITO), indium zinc oxide (IZO), zinc oxide (ZnO), indium oxide (In₂O₃), indium gallium oxide (IGO), and/or aluminum zinc oxide (AZO). According to some embodiments, the pixel electrode 210 may have a three-layer structure of ITO layer/Ag layer/ITO layer.

A bank layer 123 may be located over the pixel electrode 210. The bank layer 123 may include an opening 123OP overlapping the pixel electrode 210 and may cover the edge of the pixel electrode 210. The bank layer 123 may include an organic insulating material. According to some embodiments, the bank layer 123 may include a transparent organic insulating material. According to some embodiments, the bank layer 123 may include an organic insulating material including a light blocking material. According to some embodiments, the bank layer 123 may include a polyimide (PI)-based binder and a pigment in which red, green, and blue colors are mixed. Alternatively, the bank layer 123 may include a cardo-based binder resin and a mixture of lactam-based black pigment and blue pigment. Alternatively, the bank layer 123 may include a carbon black. The bank layer 123 may relatively improve the contrast of a display panel.

A spacer 125 may be located over the bank layer 123. The spacer 125 may include a different material than the bank layer 123. For example, the bank layer 123 and the spacer 125 may include different materials (e.g., the bank layer 123 may include a negative photosensitive material and the spacer 125 may include a positive photosensitive material) and may be respectively formed through separate mask processes. According to some embodiments, the spacer 125 may include the same material as the bank layer 123 and may be formed together in the same mask process (e.g., a halftone mask process).

The emission layer 222 may include a high-molecular weight or low-molecular weight organic material for emitting light of a certain color. The emission layer 222 may include a material for emitting red light, green light, or blue light, depending on the light emitting diode LED.

A functional layer may be further included under and/or over the emission layer 222. For example, a first functional layer 221 may be further included between the pixel electrode 210 and the emission layer 222, and a second functional layer 223 may be further included between the emission layer 222 and the opposite electrode 230 described below. The first functional layer 221 may include a hole transport layer and/or a hole injection layer. The second functional layer 223 may include an electron transport layer and/or an electron injection layer.

The opposite electrode 230 may include a conductive material having a low work function. For example, the opposite electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. Alternatively, the opposite electrode 230 may further include a layer such as ITO, IZO, ZnO, or In₂O₃ over the (semi) transparent layer including the above material.

Unlike pixel electrodes 210 separately formed to correspond to light emitting diodes LED, the opposite electrode 230 may extend to correspond to the pixel electrodes 210. For example, a pixel electrode 210 of a light emitting diode LED and a pixel electrode 210 of another light emitting diode LED may be separated and spaced apart from each other, but the opposite electrode 230 overlapping the pixel electrodes 210 may extend to cover the pixel electrodes 210 described above.

An encapsulation layer 300 may be located over the light emitting diode LED and may include at least one inorganic encapsulation layer and at least one organic encapsulation layer. According to some embodiments, FIG. 4 illustrates that the encapsulation layer 300 includes a first inorganic encapsulation layer 310, an organic encapsulation layer 320, and a second inorganic encapsulation layer 330.

The first inorganic encapsulation layer 310 and the second inorganic encapsulation layer 330 may include one or more inorganic insulating materials among aluminum oxide, titanium oxide, tantalum oxide, hafnium oxide, zinc oxide, silicon oxide, silicon nitride, and silicon oxynitride. The first inorganic encapsulation layer 310 and the second inorganic encapsulation layer 330 may include a single layer or multiple layers including the above material. The organic encapsulation layer 320 may include a polymer-based material. The polymer-based material may include acryl-based resin, epoxy-based resin, polyimide, polyethylene, and the like. According to some embodiments, the organic encapsulation layer 320 may include acrylate.

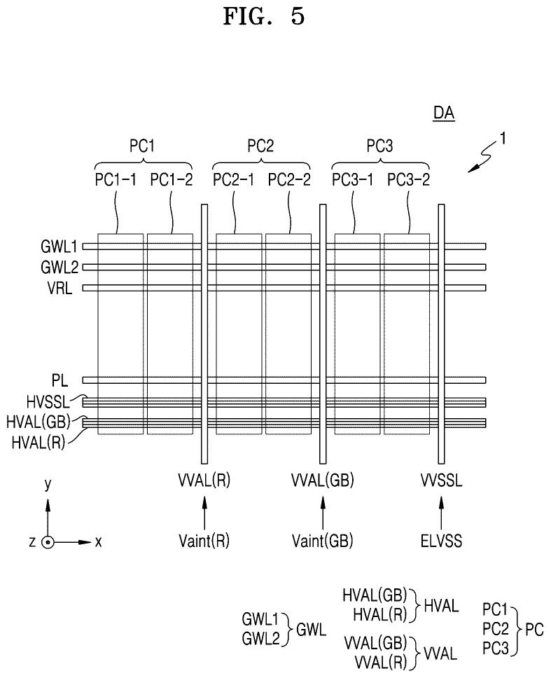

Because FIG. 4 is a cross-sectional view schematically illustrating a portion of the display apparatus 1, some of the components illustrated in FIG. 3 are omitted in the illustration. Details of the components of the display apparatus 1 will be described below with reference to FIGS. 5 to 12.

FIG. 5 is a plan view schematically illustrating a portion of lines arranged in a display area DA of the display apparatus 1, according to some embodiments.

Pixel circuits PC may be arranged in a first direction (e.g., the +x-axis direction and/or the −x-axis direction) and a second direction (e.g., the +y-axis direction and/or the −y-axis direction) in the display area DA, and FIG. 5 illustrates pixel circuits PC arranged in the same row, for example, an i-th row.

Each of the pixel circuits PC may be electrically connected to a light emitting diode. Hereinafter, for convenience of description, pixel circuits PC respectively electrically connected to first to third light emitting diodes emitting light of different colors will be described as first to third pixel circuits PC1, PC2, and PC3.

The first pixel circuit PC1, the second pixel circuit PC2, and the third pixel circuit PC3 may be sequentially arranged in the first direction (e.g., the +x-axis direction). Also, the first light emitting diode, the second light emitting diode, and the third light emitting diode may be sequentially arranged in the first direction (e.g., the +x-axis direction).

The first pixel circuit PC1 may be electrically connected to the first light emitting diode that emits light of a first color. The first pixel circuit PC1 may include a first-1 pixel circuit PC1-1 and a first-2 pixel circuit PC1-2 that are sequentially arranged in the first direction (e.g., the +x-axis direction). The first light emitting diode may include a first-1 light emitting diode and a first-2 light emitting diode that are sequentially arranged in the first direction (e.g., the +x-axis direction). The first-1 pixel circuit PC1-1 may be electrically connected to the first-1 light emitting diode, and the first-2 pixel circuit PC1-2 may be electrically connected to the first-2 light emitting diode. Each of the first-1 light emitting diode and the first-2 light emitting diode may emit light of a first color. That is, the first-1 light emitting diode and the first-2 light emitting diode may emit light of the same color.

The second pixel circuit PC2 may be electrically connected to the second light emitting diode that emits light of a second color. The second pixel circuit PC2 may be electrically connected to the second light emitting diode that emits light of a second color. The second pixel circuit PC2 may include a second-1 pixel circuit PC2-1 and a second-2 pixel circuit PC2-2 that are sequentially arranged in the second direction (e.g., the +x-axis direction). The second light emitting diode may include a second-1 light emitting diode and a second-2 light emitting diode that are sequentially arranged in the first direction (e.g., the +x-axis direction). The second-1 pixel circuit PC2-1 may be electrically connected to the second-1 light emitting diode, and the second-2 pixel circuit PC2-2 may be electrically connected to the second-2 light emitting diode. Each of the second-1 light emitting diode and the second-2 light emitting diode may emit light of a second color. That is, the second-1 light emitting diode and the second-2 light emitting diode may emit light of the same color.

The third pixel circuit PC3 may be electrically connected to the third light emitting diode that emits light of a third color. The third pixel circuit PC3 may be electrically connected to the third light emitting diode that emits light of a third color. The third pixel circuit PC3 may include a third-1 pixel circuit PC3-1 and a third-2 pixel circuit PC3-2 that are sequentially arranged in a third direction (e.g., the +x-axis direction). The third light emitting diode may include a third-1 light emitting diode and a third-2 light emitting diode that are sequentially arranged in the first direction (e.g., the +x-axis direction). The third-1 pixel circuit PC3-1 may be electrically connected to the third-1 light emitting diode, and the third-2 pixel circuit PC3-2 may be electrically connected to the third-2 light emitting diode. Each of the third-1 light emitting diode and the third-2 light emitting diode may emit light of a third color. That is, the third-1 light emitting diode and the third-2 light emitting diode may emit light of the same color.

According to some embodiments, the first color, the second color, and the third color may be light of different colors and may be selected from among red, green, and blue. The first light emitting diode, the second light emitting diode, and the third light emitting diode may emit light of different colors. For example, the first color may be red, the second color may be green, and the third color may be blue.

The first to third pixel circuits PC1, PC2, and PC3 may be repeatedly arranged in the first direction (e.g., the +x-axis direction and/or the −x-axis direction). The first pixel circuit PC1, the second pixel circuit PC2, and the third pixel circuit PC3 may be arranged in the order of the first pixel circuit PC1, the second pixel circuit PC2, and the third pixel circuit PC3 in the first direction (e.g., the +x-axis direction and/or the −x-axis direction).

Lines electrically connected to the pixel circuits PC, for example, first conductive lines (hereinafter referred to as horizontal conductive lines) extending in the first direction (e.g., +x-axis direction and/or −x-axis direction) and second conductive lines (hereinafter referred to as vertical conductive lines) extending in the second direction (e.g., the +y-axis direction and/or the −y-axis direction), may be arranged in the display area DA.

The horizontal conductive lines extending in the first direction (e.g., the +x-axis direction and/or the −x-axis direction) may include a first gate line GWL, a reference voltage line VRL, a driving voltage line PL, a horizontal sustain voltage line HVSSL, and a first initialization horizontal voltage line HVAL. For example, the first gate line GWL may include a first-1 gate line GWL1 and a first-2 gate line GWL2. Also, the first initialization horizontal voltage line HVAL may include a first-1 initialization horizontal voltage line HVAL(R) and a first-2 initialization horizontal voltage line HVAL(GB).

The vertical conductive lines extending in the second direction (e.g., the +y-axis direction and/or the −y-axis direction) may include a first initialization vertical voltage line VVAL and a vertical sustain voltage line VVSSL. For example, the first initialization vertical voltage line VVAL may include a first-1 initialization vertical voltage line VVAL(R) and a first-2 initialization vertical voltage line VVAL(GB).

The first-1 initialization vertical voltage line VVAL(R) and the first-1 initialization horizontal voltage line HVAL(R) configured to provide a first-1 initialization voltage Vaint(R) to the first pixel circuit PC1 may be electrically connected to each other in the display area DA.

The first-2 initialization vertical voltage line VVAL(GB) and the first-2 initialization horizontal voltage line HVAL(GB) configured to provide a first-2 initialization voltage Vaint(GB) to the second pixel circuit PC2 and the third pixel circuit PC3 may be electrically connected to each other in the display area DA.

The vertical sustain voltage line VVSSL and the horizontal sustain voltage line HVSSL may be electrically connected to each other in the display area DA. In this case, the vertical sustain voltage line VVSSL may be electrically connected to a common voltage ELVSS.

FIG. 5 illustrates that the second pixel circuit PC2 and the third pixel circuit PC3 are electrically connected to the same voltage line, for example, the first-2 initialization vertical voltage line VVAL(GB) and/or the first-2 initialization horizontal voltage line HVAL(GB); however, embodiments according to the present disclosure are not limited thereto. According to some embodiments, the horizontal and vertical voltage lines for applying a first initialization voltage to the second pixel circuit PC2 and the horizontal and vertical voltage lines for applying a first initialization voltage to the third pixel circuit PC3 may be provided independently of each other.

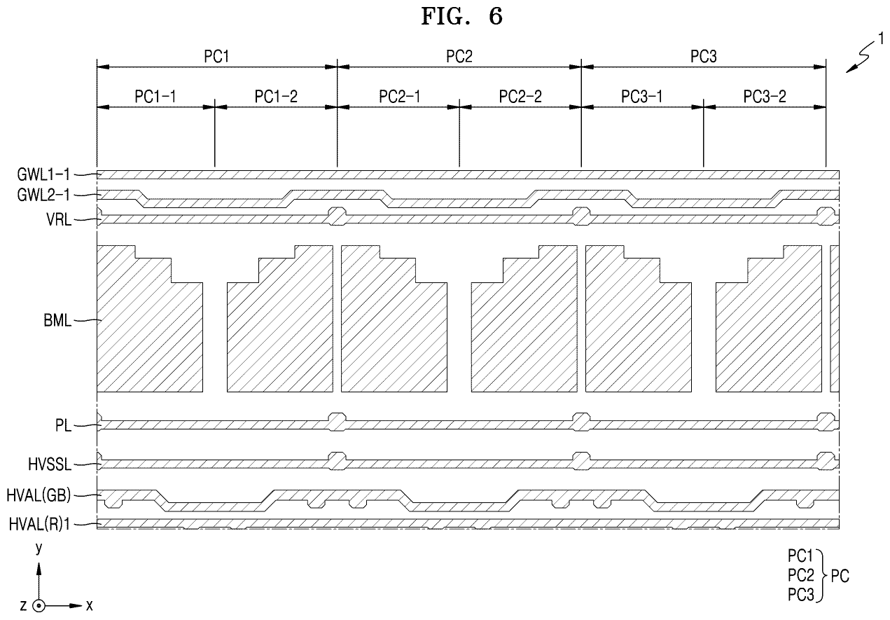

FIGS. 6 to 12 are plan views illustrating a process of forming a pixel circuit PC included in the display apparatus 1, according to some embodiments.

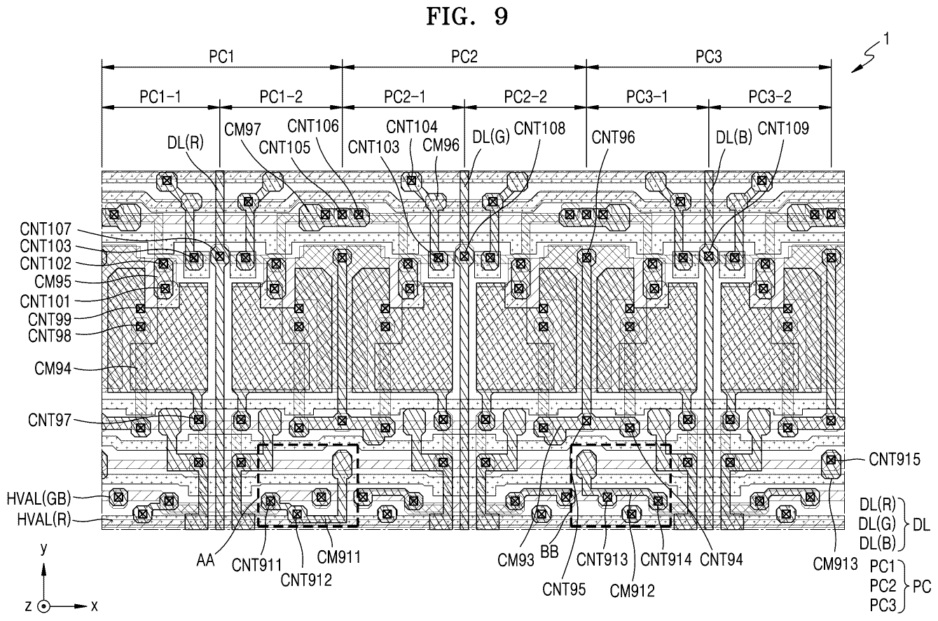

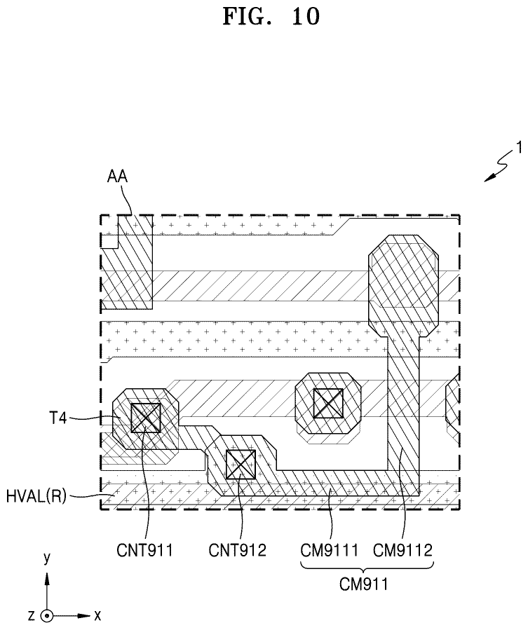

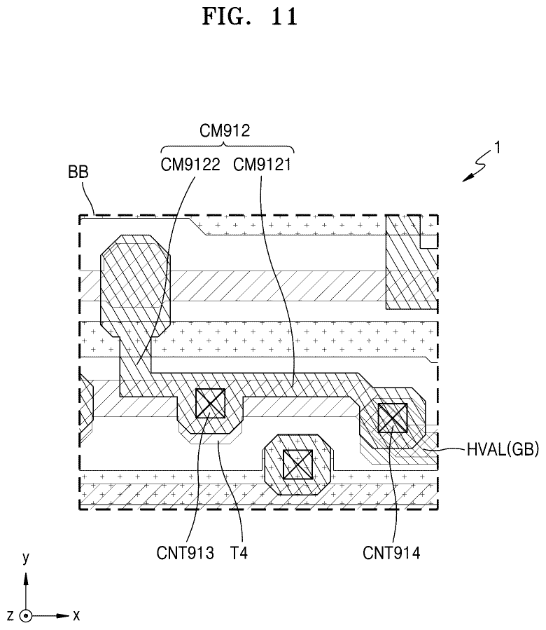

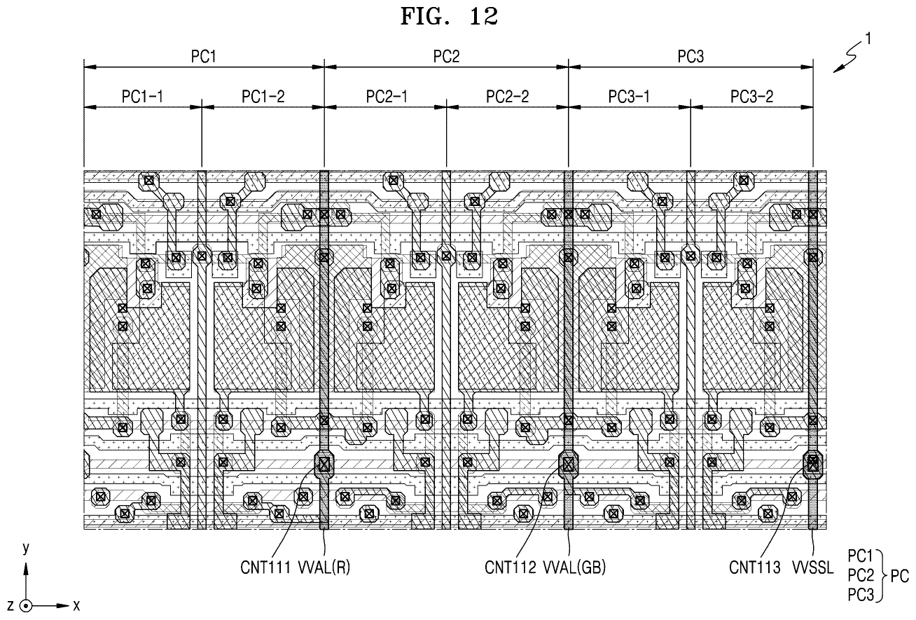

For example, FIG. 10 is an enlarged view of region AA of FIG. 9, and FIG. 11 is an enlarged view of region BB of FIG. 9. FIG. 12 may correspond to a planar structure of the pixel circuit PC of the display apparatus 1 described with reference to FIG. 4.

Referring to FIGS. 4 and 6, a first-11 gate line GWL1-1, a first-21 gate line GWL2-1, a reference voltage line VRL, a bottom metal layer BML, a driving voltage line PL, a horizontal sustain voltage line HVSSL, a first-11 initialization horizontal voltage line HVAL(R)1, and a first-2 initialization horizontal voltage line HVAL(GB) may be located over a substrate 100.

The first-11 gate line GWL1-1, the first-21 gate line GWL2-1, the reference voltage line VRL, the driving voltage line PL, the horizontal sustain voltage line HVSSL, the first-11 initialization horizontal voltage line HVAL(R)1, and the first-2 initialization horizontal voltage line HVAL(GB) may extend in the first direction (e.g., the +x-axis direction and/or the −x-axis direction) to intersect a first pixel circuit PC1, a second pixel circuit PC2, and a third pixel circuit PC3.

The first-11 initialization horizontal voltage line HVAL(R)1, the first-2 initialization horizontal voltage line HVAL(GB), the horizontal sustain voltage line HVSSL, the driving voltage line PL, the bottom metal layer BML, the reference voltage line VRL, the first-21 gate line GWL2-1, and the first-11 gate line GWL1-1 may be arranged on the same layer and may be sequentially arranged to be spaced apart from each other in the second direction (e.g., the +y-axis direction).

The bottom metal layer BML may be provided as a plurality of bottom metal layers BML to correspond to the number of pixel circuits PC. For example, as illustrated in FIG. 6, six bottom metal layers BML may respectively correspond to a first-1 pixel circuit PC1-1, a first-2 pixel circuit PC1-2, a second-1 pixel circuit PC2-1, a second-2 pixel circuit PC2-2, a third-1 pixel circuit PC3-1, and a third-2 pixel circuit PC3-2. The plurality of bottom metal layers BML may be provided in an island shape to be spaced apart from each other. The bottom metal layer BML may have an isolated shape.

A first insulating layer 111 may be located over the structure illustrated in FIG. 6, for example, the first-11 gate line GWL1-1, the first-21 gate line GWL2-1, the reference voltage line VRL, the bottom metal layer BML, the driving voltage line PL, the first-11 initialization horizontal voltage line HVAL(R)1, and the first-2 initialization horizontal voltage line HVAL(GB).

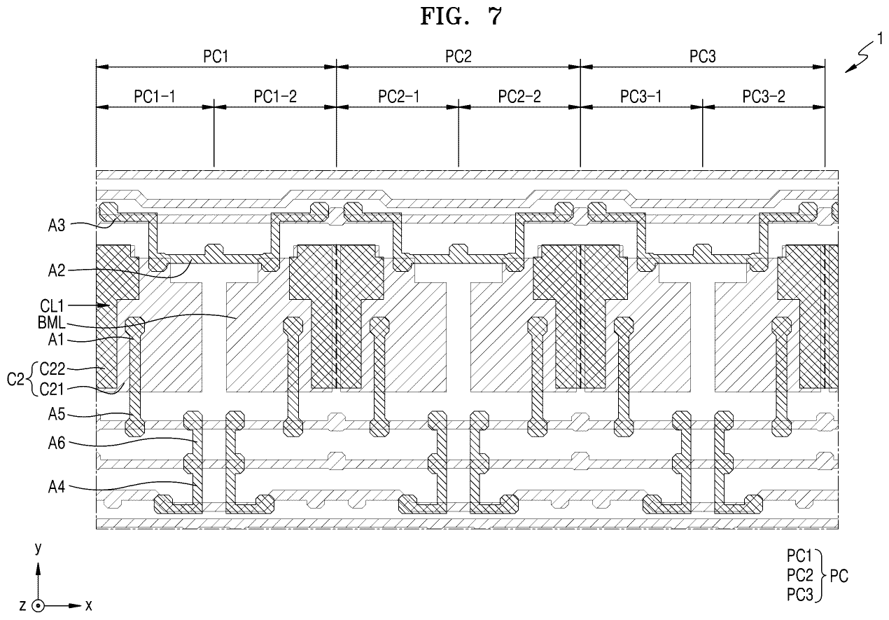

Referring to FIG. 4 and FIG. 7, first to sixth semiconductor layers A1, A2, A3, A4, A5, and A6 and a first conductive layer CL1 may be located over the first insulating layer 111. The first to sixth semiconductor layers A1, A2, A3, A4, A5, and A6 may include the same material.

The first semiconductor layer A1 and the fifth semiconductor layer A5 may be integrally connected to each other. The second semiconductor layer A2 and the third semiconductor layer A3 may be integrally connected to each other. The fourth semiconductor layer A4 and the fifth semiconductor layer A6 may be integrally connected to each other. The first semiconductor layer A1 may be arranged adjacent to the second semiconductor layer A2 and the third semiconductor layer A3 and they may be separated and spaced apart from each other. The fifth semiconductor layer A5 may be arranged adjacent to the sixth semiconductor layer A6 and may be separated and spaced apart from each other.

The first conductive layer CL1 may be arranged to overlap the bottom metal layer BML. At least a portion of the bottom metal layer BML overlapping the first conductive layer CL1 may be a first electrode C21 of a second capacitor C2. Also, at least a portion of the first conductive layer CL1 overlapping the bottom metal layer BML may be a second electrode C22 of the second capacitor C2. That is, the bottom metal layer BML may include the first electrode C21 of the second capacitor C2, and the first conductive layer CL1 may include the second electrode C22 of the second capacitor C2.

The first conductive layer CL1 may be provided as a plurality of first conductive layers CL1 to correspond to the number of pixel circuits PC. For example, as illustrated in FIG. 7, six first conductive layers CL1 may respectively correspond to the first-1 pixel circuit PC1-1, the first-2 pixel circuit PC1-2, the second-1 pixel circuit PC2-1, the second-2 pixel circuit PC2-2, the third-1 pixel circuit PC3-1, and the third-2 pixel circuit PC3-2. The first conductive layer CL1 may be provided in an island shape to be spaced apart from the first to sixth semiconductor layers A1, A2, A3, A4, A5, and A6. The first conductive layer CL1 may have an isolated shape.

Accordingly, the second capacitor C2 may be provided as a plurality of second capacitors C2 to correspond to the number of pixel circuits PC. For example, as illustrated in FIG. 6, the second capacitor C2 may be provided as six capacitors C2 to respectively correspond to the first-1 pixel circuit PC1-1, the first-2 pixel circuit PC1-2, the second-1 pixel circuit PC2-1, the second-2 pixel circuit PC2-2, the third-1 pixel circuit PC3-1, and the third-2 pixel circuit PC3-2.

The first conductive layers CL1 arranged in two adjacent pixel circuits PC may be integrally connected to each other. For example, the first conductive layers CL1 arranged in the first pixel circuit PC1 and the second pixel circuit PC2 may be integrally connected to each other, and the first conductive layers CL1 arranged in the second pixel circuit PC2 and the third pixel circuit PC3 may be integrally connected to each other.

A second insulating layer 112 may be located over the structure illustrated in FIG. 7, for example, the first to sixth semiconductor layers A1, A2, A3, A4, A5, and A6 and the first conductive layer CL1.

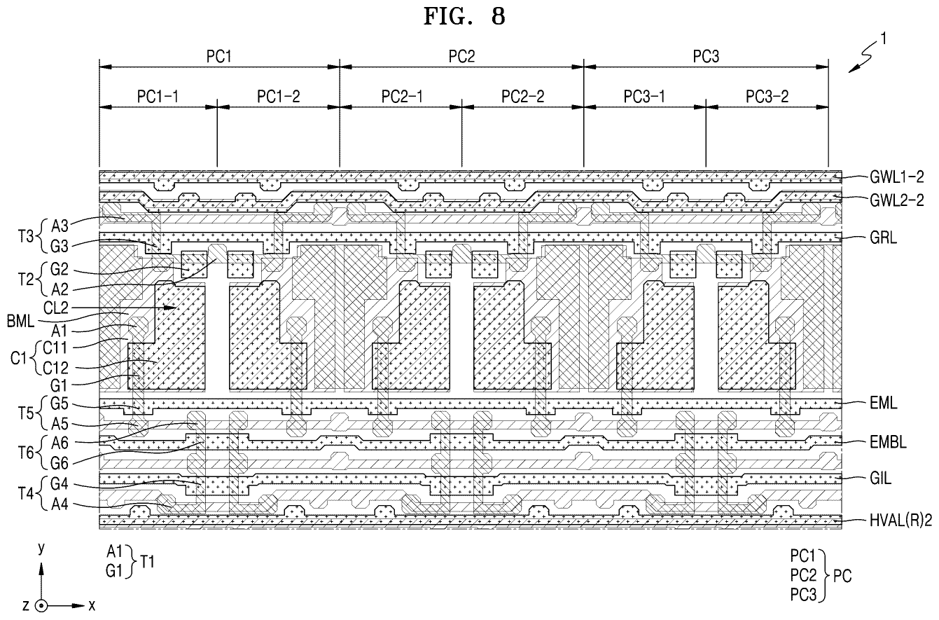

Referring to FIG. 4 and FIG. 8, a first-12 gate line GWL1-2, a first-22 gate line GWL2-2, a second gate line GRL, a third gate line EML, a fourth gate line GIL, a fifth gate line EMBL, a first-12 initialization horizontal voltage line HVAL(R)2, a second gate electrode G2, and a second conductive layer CL2 may be located over the second insulating layer 112.

The first-12 gate line GWL1-2, the first-22 gate line GWL2-2, the second gate line GRL, the third gate line EML, the fourth gate line GIL, the fifth gate line EMBL, and the first-12 initialization horizontal voltage line HVAL(R)2 may extend in the first direction (e.g., the +x-axis direction and/or the −x-axis direction) to intersect the first pixel circuit PC1, the second pixel circuit PC2, and the third pixel circuit PC3. The first-12 gate line GWL1-2, the first-22 gate line GWL2-2, the second gate line GRL, the second gate electrode G2, the second conductive layer CL2, the third gate line EML, the fifth gate line EMBL, the fourth gate line GIL, and the first-12 initialization horizontal voltage line HVAL(R)2 may be sequentially arranged to be spaced apart from each other in the second direction (e.g., the −y-axis direction).

The second gate electrode G2 may be provided as a plurality of second gate electrodes G2 to correspond to the number of pixel circuits PC. For example, as illustrated in FIG. 8, six second gate electrodes G2 may respectively correspond to the first-1 pixel circuit PC1-1, the first-2 pixel circuit PC1-2, the second-1 pixel circuit PC2-1, the second-2 pixel circuit PC2-2, the third-1 pixel circuit PC3-1, and the third-2 pixel circuit PC3-2. The plurality of second gate electrodes G2 may be provided in an island shape to be spaced apart from each other. The plurality of second gate electrodes G2 may have an isolated shape.

The second conductive layer CL2 may be provided as a plurality of second conductive layers CL2 to correspond to the number of pixel circuits PC. For example, as illustrated in FIG. 8, six second conductive layers CL2 may respectively correspond to the first-1 pixel circuit PC1-1, the first-2 pixel circuit PC1-2, the second-1 pixel circuit PC2-1, the second-2 pixel circuit PC2-2, the third-1 pixel circuit PC3-1, and the third-2 pixel circuit PC3-2. The plurality of second conductive layers CL2 may be provided in an island shape to be spaced apart from each other. The plurality of second conductive layers CL2 may have an isolated shape.

The first-12 gate line GWL1-2 may overlap the first-11 gate line GWL1-1 (see FIG. 6). The first-12 gate line GWL1-2 may be electrically connected to the first-11 gate line GWL1-1 (see FIG. 6). For example, according to some embodiments, the first-12 gate line GWL1-2 and the first-11 gate line GWL1-1 (see FIG. 6) may be connected to each other through contact holes at designated intervals. The first-11 gate line GWL1-1 (see FIG. 6) and the first-12 gate line GWL1-2 will be collectively referred to as the first-1 gate line GWL1 (see FIG. 5).

The first-22 gate line GWL2-2 may overlap the first-21 gate line GWL2-1 (see FIG. 6). The first-22 gate line GWL2-2 may be electrically connected to the first-21 gate line GWL2-1 (see FIG. 6). For example, according to some embodiments, the first-22 gate line GWL2-2 and the first-21 gate line GWL2-1 (see FIG. 6) may be connected to each other through contact holes at designated intervals. The first-21 gate line GWL2-1 (see FIG. 6) and the first-22 gate line GWL2-2 will be collectively referred to as the first-2 gate line GWL2 (see FIG. 5).

At least a portion of the second gate line GRL may overlap the third semiconductor layer A3. A portion of the second gate line GRL overlapping the third semiconductor layer A3 may be a third gate electrode G3. That is, the second gate line GRL may include the third gate electrode G3. The third semiconductor layer A3 and the third gate electrode G3 may form a third transistor T3. That is, the third transistor T3 may include the third semiconductor layer A3 and the third gate electrode G3.

The second gate electrode G2 may overlap the second semiconductor layer A2. The second semiconductor layer A2 and the second gate electrode G2 may form a second transistor T2. That is, the second transistor T2 may include the second semiconductor layer A2 and the second gate electrode G2.

At least a portion of the second conductive layer CL2 may overlap the first semiconductor layer A1. A portion of the second conductive layer CL2 overlapping the first semiconductor layer A1 may be a first gate electrode G1. That is, the second conductive layer CL2 may include the first gate electrode G1. The first semiconductor layer A1 and the first gate electrode G1 may form a first transistor T1. That is, the first transistor T1 may include the first semiconductor layer A1 and the first gate electrode G1.

At least a portion of the third gate line EML may overlap the fifth semiconductor layer A5. A portion of the third gate line EML overlapping the fifth semiconductor layer A5 may be a fifth gate electrode G5. That is, the third gate line EML may include the fifth gate electrode G5. The fifth semiconductor layer A5 and the fifth gate electrode G5 may form a fifth transistor T5. That is, the fifth transistor T5 may include the fifth semiconductor layer A5 and the fifth gate electrode G5.

At least a portion of the fifth gate line EMBL may overlap the sixth semiconductor layer A6. A portion of the fifth gate line EMBL overlapping the sixth semiconductor layer A6 may be a sixth gate electrode G6. That is, the fifth gate line EMBL may include the sixth gate electrode G6. The sixth semiconductor layer A6 and the sixth gate electrode G6 may form a sixth transistor T6. That is, the sixth transistor T6 may include the sixth semiconductor layer A6 and the sixth gate electrode G6.

At least a portion of the fourth gate line GIL may overlap the fourth semiconductor layer A4. A portion of the fourth gate line GIL overlapping the fourth semiconductor layer A4 may be a fourth gate electrode G4. That is, the fourth gate line GIL may include the fourth gate electrode G4. The fourth semiconductor layer A4 and the fourth gate electrode G4 may form a fourth transistor T4. That is, the fourth transistor T4 may include the fourth semiconductor layer A4 and the fourth gate electrode G4.

The first-12 initialization horizontal voltage line HVAL(R)2 may overlap the first-11 initialization horizontal voltage line HVAL(R)1 (see FIG. 6). The first-12 initialization horizontal voltage line HVAL(R)2 may be electrically connected to the first-11 initialization horizontal voltage line HVAL(R)1 (see FIG. 6). For example, according to some embodiments, the first-12 initialization horizontal voltage line HVAL(R)2 and the first-11 initialization horizontal voltage line HVAL(R)1 (see FIG. 6) may be connected to each other through a contact hole in the non-display area NDA (see FIG. 1). The first-11 initialization horizontal voltage line HVAL(R)1 (see FIG. 6) and the first-12 initialization horizontal voltage line HVAL(R)2 will be collectively referred to as the first-1 initialization horizontal voltage line HVAL(R) (see FIG. 5).

The second conductive layer CL2 may be arranged to overlap the bottom metal layer BML. At least a portion of the bottom metal layer BML overlapping the second conductive layer CL2 may be a first electrode C11 of the first capacitor C1. Also, at least a portion of the first conductive layer CL1 overlapping the bottom metal layer BML may be a second electrode C12 of the first capacitor C1. That is, the bottom metal layer BML may include the first electrode C11 of the first capacitor C1, and the second conductive layer CL2 may include the second electrode C12 of the first capacitor C1.

Each of the first to sixth transistors T1, T2, T3, T4, T5, and T6 and the first capacitor C1 may be provided in plurality to correspond to the number of pixel circuits PC. For example, as illustrated in FIG. 6, each of the first to sixth transistors T1, T2, T3, T4, T5, and T6 and the first capacitor C1 may be provided in six to respectively correspond to the first-1 pixel circuit PC1-1, the first-2 pixel circuit PC1-2, the second-1 pixel circuit PC2-1, the second-2 pixel circuit PC2-2, the third-1 pixel circuit PC3-1, and the third-2 pixel circuit PC3-2.

A third insulating layer 113 may be located over the structure illustrated in FIG. 8, for example, the first-12 gate line GWL1-2, the first-22 gate line GWL2-2, the second gate line GRL, the third gate line EML, the fourth gate line GIL, the fifth gate line EMBL, the first-12 initialization horizontal voltage line HVAL(R)2, the second gate electrode G2, and the second conductive layer CL2.

Referring to FIGS. 4 to 9, a plurality of connection electrodes and a data line DL may be located over the third insulating layer 113.

A 93rd connection electrode CM93 may contact the fifth semiconductor layer A5 of the fifth transistor T5 through a 94th contact hole CNT94. The 93rd connection electrode CM93 may contact the driving voltage line PL through a 95th contact hole CNT95. The 93rd connection electrode CM93 may contact the first conductive layer CL1 through a 96th contact hole CNT96. Thus, the 93rd connection electrode CM93 may electrically connect the fifth transistor T5, the driving voltage line PL, and the second electrode C22 of the second capacitor C2.

A 94th connection electrode CM94 may contact the sixth semiconductor layer A6 of the sixth transistor T6 through a 97th contact hole CNT97. The 94th connection electrode CM94 may contact the first semiconductor layer A1 of the first transistor T1 through a 98th contact hole CNT98. The 94th connection electrode CM94 may contact the bottom metal layer BML through a 99th contact hole CNT99. Thus, the 94th connection electrode CM94 may electrically connect the sixth transistor T6, the first transistor T1, the first electrode C11 of the first capacitor C1, and the first electrode C21 of the second capacitor C2.

A 95th connection electrode CM95 may contact the second conductive layer CL2 through a 101st contact hole CNT101. The 95th connection electrode CM95 may contact the second semiconductor layer A2 of the second transistor T2 and the third semiconductor layer A3 of the third transistor T3 through a 102nd contact hole CNT102. Thus, the 95th connection electrode CM95 may electrically connect the first gate electrode G1 of the first transistor T1, the second electrode C12 of the first capacitor C1, the second transistor T2, and the third transistor T3.

A 96th connection electrode CM96 may contact the second gate electrode G2 of the second transistor T2 through a 103rd contact hole CNT103. The 96th connection electrode CM96 may contact the first-1 gate line GWL1 or the first-2 gate line GWL2 through a 104th contact hole CNT104. Thus, the 96th connection electrode CM96 may electrically connect the second transistor T2 and the first gate line GWL.

A 97th connection electrode CM97 may contact the reference voltage line VRL through a 105th contact hole CNT105. The 97th connection electrode CM97 may contact the semiconductor layer of the third transistor T3 through a 106th contact hole CNT106. Thus, the 97th connection electrode CM97 may electrically connect the reference voltage line VRL and the third transistor T3.

Referring to FIGS. 9 and 10, a first connection electrode CM911 may contact the fourth semiconductor layer A4 of the fourth transistor T4 of the first pixel circuit PC1 (e.g., the first-2 pixel circuit PC1-2) through a first-1 contact hole CNT911. The first-1 contact hole CNT911 may pass through the second insulating layer 112 and the third insulating layer 113. The first connection electrode CM911 may contact the first-1 initialization horizontal voltage line HVAL(R) through a first-2 contact hole CNT912. The first-2 contact hole CNT912 may pass through the third insulating layer 113. Thus, by the first connection electrode CM911, the first-1 initialization horizontal voltage line HVAL(R) may be electrically connected to the fourth transistor T4 of the first pixel circuit PC1 (e.g., the first-2 pixel circuit PC1-2). The first connection electrode CM911 may be provided in an island shape to be spaced apart from another connection electrode arranged on the same layer. The first connection electrode CM911 may have an isolated shape.

The first connection electrode CM911 may include a first-1 connection electrode portion CM9111 and a first-2 connection electrode portion CM9112. The first-1 connection electrode portion CM9111 may extend in the first direction (e.g., the +x-axis direction and/or the −x-axis direction) and may be electrically connected to each of the fourth transistor T4 of the first pixel circuit PC1 (e.g., the first-2 pixel circuit PC1-2) and the first-1 initialization horizontal voltage line HVAL(R). The first-2 connection electrode portion CM9112 may extend in the second direction (e.g., the +y-axis direction) from an end portion of the first-1 connection electrode portion CM9111. At least a portion of the first-2 connection electrode portion CM9112 may be arranged at the boundary between the first pixel circuit PC1 (e.g., the first-2 pixel circuit PC1-2) and the second pixel circuit PC2 (e.g., the second-1 pixel circuit PC2-1).

Referring to FIGS. 9 and 11, a second connection electrode CM912 may contact the fourth semiconductor layer A4 of the fourth transistor T4 of the third pixel circuit PC3 (e.g., the third-1 pixel circuit PC3-1) through a second-1 contact hole CNT913. The second-1 contact hole CNT913 may pass through the second insulating layer 112 and the third insulating layer 113. The second connection electrode CM912 may contact the first-2 initialization horizontal voltage line HVAL(GB) through a second-2 contact hole CNT914. The second-2 contact hole CNT914 may pass through the third insulating layer 113. Thus, by the second connection electrode CM912, the first-2 initialization horizontal voltage line HVAL(GB) may be electrically connected to the fourth transistor T4 of the third pixel circuit PC3 (e.g., the third-1 pixel circuit PC3-1). The second connection electrode CM912 may be provided in an island shape to be spaced apart from another connection electrode arranged on the same layer. The second connection electrode CM912 may have an isolated shape.

The second connection electrode CM912 may include a second-1 connection electrode portion CM9121 and a second-2 connection electrode portion CM9122. The second-1 connection electrode portion CM9121 may extend in the first direction (e.g., the +x-axis direction and/or the −x-axis direction) and may be electrically connected to each of the fourth transistor T4 of the third pixel circuit PC3 (e.g., the third-1 pixel circuit PC3-1) and the first-2 initialization horizontal voltage line HVAL(GB). The second-2 connection electrode portion CM9122 may extend in the second direction (e.g., the +y-axis direction) from an end portion of the second-1 connection electrode portion CM9121. At least a portion of the second-2 connection electrode portion CM9122 may be arranged at the boundary between the second pixel circuit PC2 (e.g., the second-2 pixel circuit PC2-2) and the third pixel circuit PC3 (e.g., the third-1 pixel circuit PC3-1).

Referring back to FIG. 9, a third connection electrode CM913 may contact the horizontal sustain voltage line HVSSL through a third contact hole CNT915. At least a portion of the second connection electrode CM912 may overlap the horizontal sustain voltage line HVSSL. The third contact hole CNT915 may pass through the first insulating layer 111, the second insulating layer 112, and the third insulating layer 113. The third connection electrode CM913 may be provided in an island shape to be spaced apart from another connection electrode arranged on the same layer. The third connection electrode CM913 may have an isolated shape.

The data line DL extend in the second direction (e.g., the +y-axis direction and/or the −y-axis direction) and may be electrically connected to the second semiconductor layer A2 of the second transistor T2. The data line DL may include a first data line DL(R), a second data line DL(G), and a third data line DL(B).

The first data line DL(R) may be arranged in the first pixel circuit PC1. For example, the first data line DL(R) may be arranged at the boundary between the first-1 pixel circuit PC1-1 and the first-2 pixel circuit PC1-2. The first data line DL(R) may be electrically connected to the semiconductor layer of the second transistor T2 of the first pixel circuit PC1 through a 107th contact hole CNT107. For example, the first data line DL(R) may be simultaneously electrically connected to the semiconductor layer of the second transistor T2 of each of the first-1 pixel circuit PC1-1 and the first-2 pixel circuit PC1-2 through the 107th contact hole CNT107.

The second data line DL(G) may be arranged in the second pixel circuit PC2. For example, the second data line DL(G) may be arranged at the boundary between the second-1 pixel circuit PC2-1 and the second-2 pixel circuit PC2-2. The second data line DL(G) may be electrically connected to the semiconductor layer of the second transistor T2 of the second pixel circuit PC2 through a 108th contact hole CNT108. For example, the second data line DL(G) may be simultaneously electrically connected to the semiconductor layer of the second transistor T2 of each of the second-1 pixel circuit PC2-1 and the second-2 pixel circuit PC2-2 through the 108th contact hole CNT108.

The third data line DL(B) may be arranged in the third pixel circuit PC3. For example, the third data line DL(B) may be arranged at the boundary between the third-1 pixel circuit PC3-1 and the third-2 pixel circuit PC3-2. The third data line DL(B) may be electrically connected to the semiconductor layer of the second transistor T2 of the third pixel circuit PC3 through a 109th contact hole CNT109. For example, the third data line DL(B) may be simultaneously electrically connected to the semiconductor layer of the second transistor T2 of each of the third-1 pixel circuit PC3-1 and the third-2 pixel circuit PC3-2 through the 109th contact hole CNT109.

A fourth insulating layer 114 may be located over the structure illustrated in FIG. 9, for example, the plurality of connection electrodes and the data line DL.

Referring to FIG. 4 and FIG. 9 to FIG. 12, a first-1 initialization vertical voltage line VVAL(R), a first-2 initialization vertical voltage line VVAL(GB), and a vertical sustain voltage line VVSSL may be located over the fourth insulating layer 114.

The first-1 initialization vertical voltage line VVAL(R), the first-2 initialization vertical voltage line VVAL(GB), and the vertical sustain voltage line VVSSL may extend in the second direction (e.g., the +y-axis direction and/or the −y-axis direction). The first-1 initialization vertical voltage line VVAL(R), the first-2 initialization vertical voltage line VVAL(GB), and the vertical sustain voltage line VVSSL may be arranged on the same layer and may be sequentially arranged to be spaced apart from each other in the first direction (e.g., the +x-axis direction).

The first-1 initialization vertical voltage line VVAL(R) may be electrically connected to the first-1 initialization horizontal voltage line HVAL(R). The first-1 initialization vertical voltage line VVAL(R) may be connected to the first connection electrode CM911 through a 111th contact hole CNT111. The 111th contact hole CNT111 may pass through the fourth insulating layer 114. The first connection electrode CM911 may electrically connect the first-1 initialization horizontal voltage line HVAL(R) and the first-1 initialization vertical voltage line VVAL(R). The first-1 initialization horizontal voltage line HVAL(R), the first-1 initialization vertical voltage line VVAL(R), and the first connection electrode CM911 may be arranged on different layers.

For example, the first-2 connection electrode portion CM9112 may be electrically connected to the first-1 initialization vertical voltage line VVAL(R). The first-1 initialization vertical voltage line VVAL(R) may be arranged at the boundary between the first pixel circuit PC1 (e.g., the first-2 pixel circuit PC1-2) and the second pixel circuit PC2 (e.g., the second-1 pixel circuit PC2-1). At least a portion of the first-2 connection electrode portion CM9112 may overlap the first-1 initialization vertical voltage line VVAL(R).

The first-2 initialization vertical voltage line VVAL(GB) may be electrically connected to the first-2 initialization horizontal voltage line HVAL(GB). The first-2 initialization vertical voltage line VVAL(GB) may be connected to the second connection electrode CM912 through a 112th contact hole CNT112. The 112th contact hole CNT112 may pass through the fourth insulating layer 114. The second connection electrode CM912 may electrically connect the first-2 initialization horizontal voltage line HVAL(GB) and the first-2 initialization vertical voltage line VVAL(GB). The first-2 initialization horizontal voltage line HVAL(GB), the first-2 initialization vertical voltage line VVAL(GB), and the second connection electrode CM912 may be arranged on different layers.

For example, the second-2 connection electrode portion CM9122 may be electrically connected to the first-2 initialization vertical voltage line VVAL(GB). The first-2 initialization vertical voltage line VVAL(GB) may be arranged at the boundary between the second pixel circuit PC2 (e.g., the second-2 pixel circuit PC2-2) and the third pixel circuit PC3 (e.g., the third-1 pixel circuit PC3-1). At least a portion of the second-2 connection electrode portion CM9122 may overlap the first-2 initialization vertical voltage line VVAL(GB).

The vertical sustain voltage line VVSSL may be electrically connected to the horizontal sustain voltage line HVSSL. The vertical sustain voltage line VVSSL may be connected to the third connection electrode CM913 through a 113th contact hole CNT113. The 113th contact hole CNT113 may pass through the fourth insulating layer 114. The third connection electrode CM913 may electrically connect the vertical sustain voltage line VVSSL and the horizontal sustain voltage line HVSSL. At least a portion of the third connection electrode CM913 may overlap the vertical sustain voltage line VVSSL. The horizontal sustain voltage line HVSSL, the vertical sustain voltage line VVSSL, and the third connection electrode CM913 may be arranged on different layers.

According to the display apparatus described with reference to FIGS. 5 to 12, because the first gate line GWL, the second gate line GRL, the third gate line EML, the fourth gate line GIL, the fifth gate line EMBL, the data line DL, the reference voltage line VRL, the driving voltage line PL, the sustain voltage line VSSL, and the first initialization voltage line VAL may be arranged at a high density, the space efficiency thereof may be relatively improved. Thus, the bottom metal layer BML, the first conductive layer CL1, and the second conductive layer CL2 may be arranged in a relatively large area. Accordingly, the first electrode C11 and the second electrode C12 of the first capacitor C1 may be arranged in a large area, and the first electrode C21 and the second electrode C22 of the second capacitor C2 may be arranged in a large area. That is, the capacitance of the first capacitor C1 and the second capacitor C2 may be relatively improved. Thus, the phenomenon of spots being viewed in the display apparatus 1 may be relatively reduced to relatively improve the quality of the display apparatus 1.

According to some embodiments, the phenomenon of spots being visible in the display apparatus may be relatively reduced to relatively improve the quality of the display apparatus.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of embodiments according to the present disclosure as defined by the following claims, and their equivalents.

1 what is claimed is:

1. A display apparatus comprising:
a first pixel circuit, a second pixel circuit, and a third pixel circuit each comprising a plurality of transistors, a first capacitor, and a second capacitor, wherein the first pixel circuit, the second pixel circuit, and the third pixel circuit are over a substrate and arranged in a first direction;
a first light emitting diode electrically connected to the first pixel circuit;
a second light emitting diode electrically connected to the second pixel circuit;
a third light emitting diode electrically connected to the third pixel circuit;
a horizontal sustain voltage line extending in the first direction;
a first-1 initialization horizontal voltage line extending in the first direction and electrically connected to any one of the plurality of transistors of the first pixel circuit;
a first-2 initialization horizontal voltage line extending in the first direction and electrically connected to any one of the plurality of transistors of each of the second pixel circuit and the third pixel circuit;
a vertical sustain voltage line extending in a second direction intersecting the first direction and electrically connected to the horizontal sustain voltage line;
a first-1 initialization vertical voltage line extending in the second direction and electrically connected to the first-1 initialization horizontal voltage line; and
a first-2 initialization vertical voltage line extending in the second direction and electrically connected to the first-2 initialization horizontal voltage line.

2. The display apparatus of claim 1, further comprising a first connection electrode electrically connecting the first-1 initialization horizontal voltage line and the first-1 initialization vertical voltage line to each other,
wherein the first-1 initialization horizontal voltage line, the first-1 initialization vertical voltage line, and the first connection electrode are arranged on different layers.

3. The display apparatus of claim 2, wherein the first connection electrode comprises:
a first-1 connection electrode portion extending in the first direction and electrically connected to each of any one of the plurality of transistors of the first pixel circuit and the first-1 initialization horizontal voltage line; and
a first-2 connection electrode portion extending in the second direction from an end portion of the first-1 connection electrode portion and electrically connected to the first-1 initialization vertical voltage line.

4. The display apparatus of claim 3, wherein the first-1 initialization vertical voltage line is at a boundary between the first pixel circuit and the second pixel circuit, and
at least a portion of the first-2 connection electrode portion overlaps the first-1 initialization vertical voltage line.

5. The display apparatus of claim 2, wherein the first connection electrode has an island shape and is spaced apart from another connection electrode on a same layer as the first connection electrode.

6. The display apparatus of claim 1, further comprising a second connection electrode electrically connecting the first-2 initialization horizontal voltage line and the first-2 initialization vertical voltage line to each other,
wherein the first-2 initialization horizontal voltage line, the first-2 initialization vertical voltage line, and the second connection electrode are arranged on different layers.

7. The display apparatus of claim 6, wherein the second connection electrode comprises:
a second-1 connection electrode portion extending in the first direction and electrically connected to each of any one of the plurality of transistors of the third pixel circuit and the first-2 initialization horizontal voltage lines; and
a second-2 connection electrode portion extending in the second direction from an end portion of the second-1 connection electrode portion and electrically connected to the first-2 initialization vertical voltage line.

8. The display apparatus of claim 7, wherein the first-2 initialization vertical voltage line is at a boundary between the second pixel circuit and the third pixel circuit, and
at least a portion of the second-2 connection electrode portion overlaps the first-2 initialization vertical voltage line.

9. The display apparatus of claim 6, wherein the second connection electrode has an island shape and is spaced apart from another connection electrode on a same layer as the second connection electrode.

10. The display apparatus of claim 1, further comprising a third connection electrode electrically connecting the horizontal sustain voltage line and the vertical sustain voltage line to each other,
wherein the horizontal sustain voltage line, the vertical sustain voltage line, and the third connection electrode are arranged on different layers.

11. The display apparatus of claim 10, wherein at least a portion of the third connection electrode overlaps the horizontal sustain voltage line.

12. The display apparatus of claim 10, wherein at least a portion of the third connection electrode overlaps the vertical sustain voltage line.

13. The display apparatus of claim 10, wherein the third connection electrode has an island shape and is spaced apart from another connection electrode arranged on a same layer as the third connection electrode.

14. The display apparatus of claim 1, wherein the horizontal sustain voltage line, the first-1 initialization horizontal voltage line, and the first-2 initialization horizontal voltage line are arranged on a same layer.

15. The display apparatus of claim 1, wherein the vertical sustain voltage line, the first-1 initialization vertical voltage line, and the first-2 initialization vertical voltage line are on a same layer.

16. The display apparatus of claim 1, wherein the first-1 initialization horizontal voltage line, the first-2 initialization horizontal voltage line, and the horizontal sustain voltage line are sequentially arranged in the second direction.

17. The display apparatus of claim 1, wherein the first-1 initialization vertical voltage line, the first-2 initialization vertical voltage line, and the vertical sustain voltage line are sequentially arranged in the first direction.

18. The display apparatus of claim 1, wherein the first light emitting diode, the second light emitting diode, and the third light emitting diode emit light of different colors.

19. The display apparatus of claim 1, wherein the first pixel circuit comprises a first-1 pixel circuit and a first-2 pixel circuit arranged in the first direction, and
the first light emitting diode comprises a first-1 light emitting diode and a first-2 light emitting diode arranged in the first direction,
wherein the first-1 light emitting diode and the first-2 light emitting diode are configured to emit light of a same color.

20. A tablet personal computer comprising the display apparatus of claim 1.
